(19) United States
(12) Patent Application Publication
(10) Pub. No.: US 2009/0109608 A1
(43) Pub. Date: Apr. 30, 2009

(54) ELECTRONIC APPARATUS

(75) Inventors: Hideki Watanabe, Ome-shi (JP); Hiroshi Aiba, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/207,344

(22) Filed: Sep. 9, 2008

(30) Foreign Application Priority Data
Oct. 30, 2007 (JP) 2007-282251

(51) Int. Cl. H05K 7/20; H05K 7/00

(52) U.S. Cl. 361/679.32; 361/760

(57) ABSTRACT

According to one embodiment, an electronic apparatus includes a housing, a main circuit board contained in the housing, a memory controller mounted on the main circuit board, only one memory slot mounted on the main circuit board, and only one memory module attached to the memory slot. The memory controller is of a specification that allows the memory controller to access-control up to one memory slot to which a memory module is attached in addition to an on-board memory which is to be directly mounted on the main circuit board. No on-board memory is mounted on the main circuit board, only the memory module is mounted as a memory on the main circuit board. Access control of the memory module is executed by the memory controller.

### CROSS-REFERENCE TO RELATED APPLICATIONS

This application is based upon and claims the benefit of priority from Japanese Patent Application No. 2007-282251, filed Oct. 30, 2007, the entire contents of which are incorporated herein by reference.

### BACKGROUND

1. Field

One embodiment of the invention relates to an electronic apparatus on which a memory is mounted.

2. Description of the Related Art

An electronic apparatus such as a portable computer is provided with a memory as one of basic components. As the memory, there is, for example, an on-board memory which is directly mounted on a main circuit board to be operated. In addition, as the memory, there is a memory module which is to be attached to an expanded memory slot.

In Jpn. Pat. Appln. KOKAI Publication No. 2001-14222, an electronic apparatus provided with a plurality of expanded memory slots is disclosed. This electronic apparatus includes a CPU, two expanded memory slots, and a memory controller which can access-control the two expanded memory slots.

In Jpn. Pat. Appln. KOKAI Publication No. 9-306612, a memory slot to which a memory module is attached is disclosed. This memory slot may be mounted on a memory board. As a result of this, the memory module is mounted in a multistage configuration.

When two expanded memory slots are provided as described in Jpn. Pat. Appln. KOKAI Publication No. 2001-14222, the electronic apparatus tends to become large in size. When the memory module is made to have a multistage configuration as described in Jpn. Pat. Appln. KOKAI Publication No. 9-306612, the electronic apparatus tends to increase in thickness.

In recent years, the demand for reduction in the size of an electronic apparatus is great. A memory of an electronic apparatus that is reduced in size is constituted of so-called “on-board memory+memory 1 slot” in some cases. This is a memory constituted of a combination of an on-board memory which is directly mounted on a main circuit board to be operated, and one memory module mounted on a memory slot.

In this case, when the electronic apparatus is used, each of the on-board memory directly mounted on the main circuit board, and the memory module mounted on the memory slot generates heat. The temperature of the housing rises due to the heat generation. In order to reduce the temperature rise of the housing, the electronic apparatus needs countermeasures, e.g., providing the apparatus with various heat radiation devices, or the like.

Further, in such an electronic apparatus, in order to further advance the reduction in size, a memory module is often arranged in such a manner that the memory module covers an on-board memory and overlaps with the on-board memory. In this case, it is difficult to secure a sufficient space between the memory module and an inner wall surface of the housing, and there is the possibility of the temperature of the housing rising further.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary cross-sectional view schematically showing the inside of the portable computer shown in FIG. 1;

FIG. 3 is an exemplary view showing a part of the system configuration of the portable computer shown in FIG. 1; and

FIG. 4 is an exemplary cross-sectional view schematically showing the inside of a portable computer according to a second embodiment of the invention.

### DETAILED DESCRIPTION

Various embodiments according to the invention will be described hereinafter with reference to the accompanying drawings. In general, according to one embodiment of the invention, an electronic apparatus includes a housing, a main circuit board contained in the housing, a memory controller mounted on the main circuit board, only one memory slot mounted on the main circuit board, and only one memory module attached to the memory slot. The memory controller is of a specification that allows the memory controller to access-control up to one memory slot to which a memory module is attached in addition to an on-board memory which is to be directly mounted on the main circuit board. No on-board memory is mounted on the main circuit board, only the memory module is mounted as a memory on the main circuit board. Access control of the memory module is executed by the memory controller.

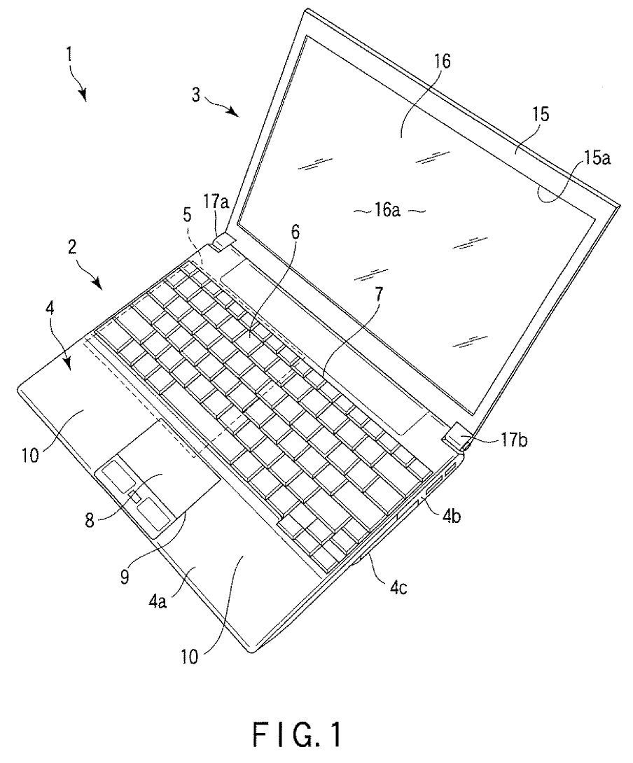

An example in which an embodiment of the present invention is applied to a portable computer will be described below on the basis of the drawings. FIGS. 1 to 3 disclose a portable computer 1 as an electronic apparatus according to a first embodiment of the present invention. As shown in FIG. 1, the portable computer 1 includes a main body 2 and a display unit 3.

The main body 2 includes a housing 4 formed into a box-like shape. A main circuit board 5 is contained in the housing 4. The housing 4 includes an upper wall 4a, peripheral wall 4b, and a lower wall 4c. The upper wall 4a is provided with a keyboard mounting section 7 to which a keyboard 6 is attached, a touch pad mounting section 9 to which a touch pad 8 is attached, and a pair of palm rests 10.

The palm rest 10 are provided at the front of the keyboard 6, and a user may often place his or her palms thereon, for example, when the user uses the keyboard 6. The palm rest 10 are one of parts of the portable computer 1 most frequently touched by the user.

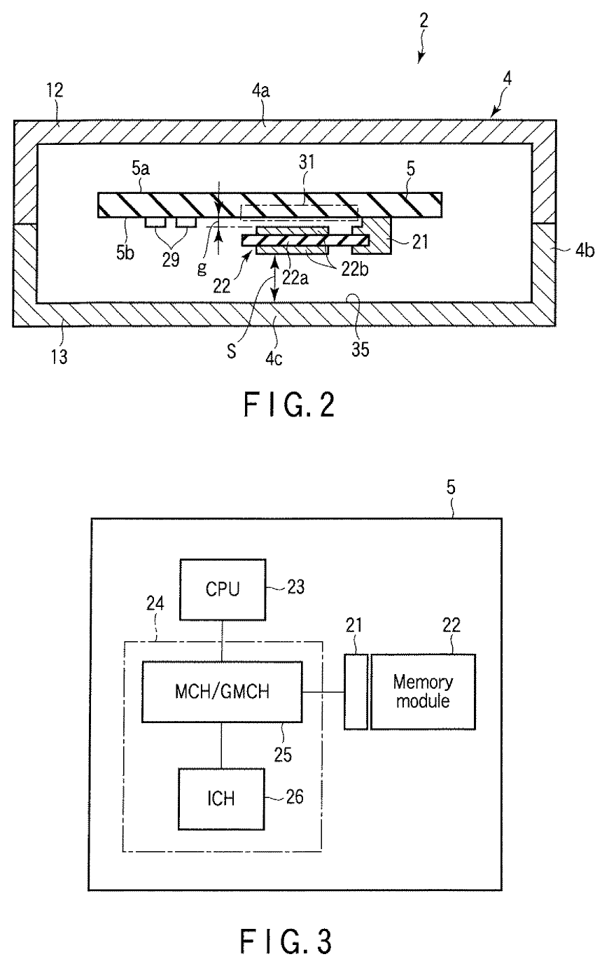

The lower wall 4c is a wall part opposed to, when the portable computer 1 is placed on an installation surface such as a desktop, the installation surface. As shown in FIG. 2, the lower wall 4c forms a space for containing the main circuit board 5 between itself and the upper wall 4a.

As shown in FIG. 2, the housing 4 includes a housing cover 12 including, for examples the upper wall 4a and a part of the peripheral wall 4b, and a housing base 13 including, for example, the lower wall 4c and a part of the peripheral wall 4b. The housing cover 12 is detachably combined with the housing base 13, whereby the housing 4 is formed.

As shown in FIG. 1 the display unit 3 includes a display housing 15, and a display device 16 contained in the display housing 15. The display device 16 includes a display screen 16a. The display screen 16a is exposed to the outside of the display housing 15 through an opening part 15a in the front of the display housing 15.

The display unit 3 is supported on a back end part of the housing 4 through a pair of hinge sections 17a and 17b. Thus, the display unit 3 is swingable between a closed position in which the display unit 3 covers the upper wall 4a from above, and an opened position in which the display unit 3 rises to expose the upper wall 4a.

FIG. 2 schematically shows the inside of the housing 4. As shown in FIG. 2, the main circuit board 5 includes a first board surface 5a opposed to the upper wall 4a of the housing 4, and a second board surface 5b opposed to the lower wall 4c. The portable computer 1 includes only one memory slot 21 mounted on the main circuit board 5, and only one memory module 22 attached to the memory slot 21. That is, the portable computer 1 includes only one memory slot 21. This only one memory slot 21 is mounted on, for example, the second board surface 5b of the main circuit board 5, and is opposed to the lower wall 4c of the housing 4.

The memory module 22 includes a sub-board 22a, and a plurality of memory chips 22b mounted on the sub-board 22a. The memory module 22 is mounted on the memory slot 21 in a posture parallel with the main circuit board 5. The memory module 22 maintains a gap g between itself and the main circuit board 5.

The memory module 22 is capable of being attached to or detached from the memory slot 21. When the user desires larger memory capacity, he or she can detach the memory module 22 from the memory slot 21, and replace the detached module 22 with a new memory module 22 having the desired memory capacity.

FIG. 3 shows a part of the system configuration of the main circuit board 5. As shown in FIG. 3, a CPU 23, and a chip set 24 including a memory controller are mounted on the main circuit board 5. The CPU 23 controls the overall operation of the portable computer 1. The chip set 24 is electrically connected to the CPU 23 and the memory slot 21, and controls transfer of data between the CPU 23 and the memory module 22.

As shown in FIG. 3, the chip set 24 includes, for example, a memory controller hub (MCH) 25, and an I/O controller hub (ICH) 26. The MCH 25 performs processing around the memory. The MCH 25 is provided with a function of a memory controller mentioned in the present invention. An example of the MCH 25 is the north bridge (trade name). The ICH 26 performs processing associated with the input/output. An example of the ICH 26 is the south bridge.

The type of a memory and the capacity thereof that may be mounted on the portable computer 1 are determined by a specification of the memory controller of the chip set 24. The chip set 24 mounted on the portable computer 1 has a specification that allows the computer 1 to have a memory capacity up to the so-called “on-board memory+memory 1 slot”. That is, the memory controller of the chip set 24 has the specification that allows the memory controller to access-control up to one memory slot to which a memory module is attached in addition to an on-board memory which is directly mounted on the main circuit board 5 to be operated.

In other words, the chip set 24 does not accept the so-called “memory 2 slot”. That is, the chip set 24 is not capable of executing access control of a plurality of memory slots which are to be mounted on the main circuit board 5.

In the portable computer 1, the on-board memory is not mounted on the main circuit board 5. The memory mounted on the portable computer 1 is only the memory module 22. Access control of the memory module 22 is executed by the memory controller of the chip set 24.

As shown in FIG. 2, any on-board memory is not present between the memory module 22 and the main circuit board 5. Further, various electronic components 29 are mounted on the main circuit board 5. All the electronic components 29 are arranged to avoid a region 31 opposed to the memory module 22 on the second board surface 5b of the main circuit board 5.

As the memory slot 21 according to this embodiment, that of a type having a relatively small connector height is employed in order that the gap g between the memory module 22 and the main circuit board 5 may be made small. In other words, a space S for preventing the heat generated from the memory module 22 from being thermally conducted to the housing 4 is secured between the memory module 22 and the inner wall surface 35 of the housing 4. Incidentally, in this description, the “connector height” implies the height from the main circuit board 5 to the connector top surface.

Next, the function of the portable computer 1 will be described below.

When the portable computer 1 is used, the memory module 22 generates heat to become a heat source. However, in this portable computer 1, the on-board memory is not mounted, and hence the memory that acts as a heat source is only the memory module 22.

As shown in FIG. 2, the memory module 22 is mounted on the second board surface 5b of the main circuit board 5, and a gap g is kept between the module 22 and the main circuit board 5. Thus, the heat generated from the memory module 22 is hardly conducted to the upper wall 4a of the housing 4 on the opposite side with the main circuit board 5 interposed between the wall 4a and the module 22. On the other hand, although the memory module 22 is opposed to the lower wall 4c of the housing 4, the space S sufficient for the air to flow therethrough is secured between the module 22 and the lower wall 4c, and hence the heat generated from the memory module 22 is also hardly conducted to the lower wall 4c.

According to the portable computer 1 having the configuration described above, it is possible to reduce the temperature rise of the housing 4. That is, in the portable computer 1 provided with a chip set 24 having the specification that enables up to one memory slot to be access-controlled in addition to the on-board memory, by making up the memory only of the memory module 22 without mounting the on-board memory, it is possible to obtain the following plural effects, and reduce the temperature rise of the housing 4.

That is, by making up the memory only of the memory module 22 without mounting the on-board memory, it is first possible to reduce the number of heat sources in the portable computer 1. This makes it possible to reduce the heat release value itself of the portable computer 1, and reduce the temperature rise of the housing 4.

In order to reduce the number of heat sources, making up the memory only of the on-board memory without mounting the memory module 22 may also be considered. However, the on-board memory may not be easily exchanged, and hence the on-board memory does not offer a high convenience to the user. On the other hand, when the memory is made up only of the memory module 22, the user may easily obtain the desired memory capacity by only changing the memory module 22. That is, it is possible to reduce the temperature rise of the housing 4 without lowering the convenience of the user.

When the on-board memory is provided, an expandable memory is limited thereby. On the other hand, as in this embodiment, even when the memory is made up only of the memory module 22, the freedom of the exchangeable memory module 22 is enhanced in such a manner that the type of the exchangeable memory module 22 is not limited by the on-board memory.

To begin with, in the specification of a chip set 24 to be mounted on a small-sized electronic apparatus, the maximum memory capacity is limited to, for example, 2 GB in many cases. Assuming a case where an on-board memory of, for example, 512 MB is mounted, the capacity of the expandable memory module 22 is limited by the on-board memory to only 1 GB. On the other hand, as in this embodiment, when the memory is constituted of only the memory module 22, it becomes possible to mount a memory module of 2 GB.

Furthermore, when the memory is made up only of the memory module 22 without mounting the on-board memory, it is not necessary to arrange a memory module 22 by overlapping the module 22 with the on-board memory so as to reduce the size of the electronic apparatus. This makes it possible to employ a memory slot having a relatively small connector height. When the memory slot 21 having a relatively small connector height may be employed, a space S through which air passes may be easily secured between the memory module 22 and the housing 4. This prevents the heat from being conducted to the housing 4, and may reduce the temperature rise of the housing 4.

In this embodiment, all the electronic components 29 mounted on the main circuit board 5 are arranged to avoid a region 31 of the main circuit board 5 opposed to the memory module 22. This makes it possible to employ a memory slot 21 having a further smaller connector height.

Here, the effect of the present invention will be exemplified by taking up an example according to this embodiment. When the memory module 22 is arranged by overlapping with the on-board memory, the connector height of the memory slot 21 is, for example, 5.8 mm. Conversely, when the on-board memory is not mounted, it becomes possible to employ a memory module 22 having a connector height of 4.6 mm.

In the case where on-board memories are mounted the main circuit board, the on-board memories are mounted on both sides of the main circuit board 5 in many cases due to the circuit and pattern layout specifications. On the other hand, when the memory is made up only of the memory module 22, it is possible to collect the heat sources on one side of the main circuit board 5.

For example, when the memory slot 21 is mounted on the second board surface 5b (i.e., the undersurface) of the main circuit board 5, it is possible to separate the upper wall 4a of the housing 4 further from the heat source. This makes it possible to further reduce the temperature rise of the upper wall 4a of the housing 4. The palm rest 10 which are one of parts most frequently touched by the user is provided on this upper wall 4a, and hence the temperature rise of the upper wall 4a may be reduced, whereby the user may use the portable computer 1 more pleasantly.

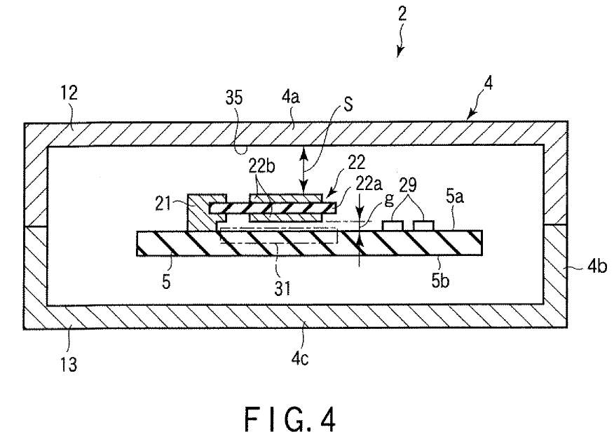

Next, a portable computer 1 as an electronic apparatus according to a second embodiment of the present invention will be described below with reference to FIG. 4. Incidentally, a configuration having a function identical with or similar to the configuration of the first embodiment will be denoted by the same reference symbol and a description thereof will be omitted.

As shown in FIG. 4, in the portable computer 1 according to this embodiment, a memory slot 21 is mounted on a first board surface 5a (i.e., a top surface) of a main circuit board 5. The remaining configurations of the portable computer 1 other than the configuration described above are identical with those of the first embodiment described above.

With such a configuration too, the number of heat sources may be reduced, and a space S may be easily secured between a memory module 22 and a housing 4, and hence the temperature rise of the housing 4 can be reduced.

The portable computer 1 according to each of the first and second embodiments of the present invention has been described above. However, the present invention is not limited to the above embodiments.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a main circuit board contained in the housing;
a memory controller mounted on the main circuit board, and is of a specification that allows the memory controller to access-control up to one memory slot to which a memory module is attached in addition to an on-board memory which is to be directly mounted on the main circuit board;
only one memory slot mounted on the main circuit board; and
only one memory module attached to the memory slot, wherein
no on-board memory is mounted on the main circuit board, only the memory module is mounted as a memory on the main circuit board, and access control of the memory module is executed by the memory controller.

2. The electronic apparatus according to claim 1, wherein
the housing includes an upper wall provided with a palm rest, and a lower wall that forms a space for containing the main circuit board between the lower wall and the upper wall,
the main circuit board includes a first board surface opposed to the upper wall, and a second board surface opposed to the lower wall, and
the memory slot is mounted on the second board surface of the main circuit board.

3. The electronic apparatus according to claim 2, further comprising electronic components mounted on the main circuit board, wherein
all the electronic components mounted on the main circuit board are arranged to avoid a region of the main circuit board opposed to the memory module.

4. The electronic apparatus according to claim 1, further comprising a chip set mounted on the main circuit board, wherein
the memory controller is provided in the chip set.
